(19) United States
(12) Patent Application Publication
(10) Pub. No.: US 2004/0061206 A1
(43) Pub. Date: Apr. 1, 2004

(54) Discrete package having insulated ceramic heat sink

(76) Inventors: Joon-Seo Son, Seoul (KR); Jong-Hwan Baek, Gimpo-city (KR); Taek-Keun Lee, Bucheon-city (KR)

Correspondence Address: KIRTON & McCONKIE, 1800 Eagle Gate Tower, 60 East South Temple Street, P.O. Box 45120, Salt Lake City, UT, 84145-0120, US

(21) Appl. No.: 10/672,346

(22) Filed: Sep. 26, 2003

(30) Foreign Application Priority Data
Sep. 27, 2002 (JP) 2002-58857

(51) Int. Cl. H01L 23/495

(52) U.S. Cl. 257/675

(57) ABSTRACT

Discrete semiconductor packages are described. The discrete package contains: a lead frame pad which has a first surface and a second surface, wherein the second surface which is the opposite surface of the first surface; leads connected to a side of the lead frame pad; a semiconductor chip attached to the first surface of the lead frame pad; a ceramic layer that directly contacts the second surface of the lead frame pad; and a molding material that entirely encapsulates the lead frame pad, the semiconductor chip, and a portion of the ceramic layer, except for a portion of the leads and the second surface of the ceramic layer. Methods for making such discrete packages are also described.

### REFERENCE TO RELATED APPLICATIONS

This application claims priority of Korean Patent Application No. 2002-58857, filed Sep. 27, 2002, the entire disclosure of which is incorporated herein by reference.

### FIELD OF THE INVENTION

The present invention relates to semiconductor packages and methods for making the same. More particularly, the present invention relates to discrete packaging for semiconductor devices having an insulated ceramic heat sink and methods for making the same.

### BACKGROUND OF THE INVENTION

FIG. 1 illustrates a cross-sectional view of a conventional discrete package 100 for semiconductor devices (also referred to as a semiconductor package, discrete package, or package). Referring to FIG. 1, the discrete package 100 has a structure in which a ceramic layer 120, a lead frame pad 130, and a semiconductor chip 140 are sequentially formed on a heat sink 110. The heat sink 110, the ceramic layer 120, the lead frame pad 130, and the semiconductor chip 140 are encapsulated by any molding material 150, such as an epoxy molding compound (EMC). To discharge heat to the outside of the package, the bottom of the heat sink 110 is usually not encapsulated and is therefore exposed to the outside of the package.

A soldering process is often performed on the heat sink 110, the ceramic layer 120, the lead frame pad 130, and the semiconductor chip 140 using a solder formed of PbSnSb. The soldering process attaches the ceramic layer 120 on the heat sink 110, the lead frame pad 130 on the ceramic layer 120, and the semiconductor chip 140 on the lead frame 130. However, as well known in the art, ceramics are materials that can be difficult to be solder to other materials. Thus, in order to attach the ceramic layer 120 to the heat sink 110 and to the lead frame pad 130, upper and lower surfaces 120a and 120b of the ceramic layer 120 are often coated with any conductive layer pattern. The conductive layer pattern may be formed of a conductive material like gold (Ag). Costs for fabricating a ceramic layer 120 coated with a conductive layer pattern are more expensive (by about three times) than a ceramic layer 120 that is not coated with a conductive layer pattern. Moreover, the soldering process must be carried out three times to successively attach the heat sink 110, the ceramic layer 120, the lead frame pad 130, and the semiconductor chip 140. This lengthy procedure can increase the costs for manufacturing the discrete package 100.

FIG. 2 is a cross-sectional view of another conventional discrete package 200. As shown in FIG. 2, the discrete package 200 contains a direct bonding copper (DBC) substrate 210 that is used for thermal insulation and discharge. The DBC substrate 210 has a structure in which a lower copper layer 212 and an upper copper layer 216 are bonded to the lower and upper surfaces, respectively, of a ceramic layer 214. A semiconductor chip 220 is attached to an upper surface of the upper copper layer 216 using a soldering process. Leads (not shown) are formed on the upper copper layer 216 of the DBC substrate 210. The DBC substrate 210 and the semiconductor chip 220 are encapsulated by any molding material 230 so that the lower surface of the lower copper layer 212 and portions of the leads connected to the upper copper layer 216 are not encapsulated and are exposed to the outside of the molding material 230.

By using the DBC substrate 210, the discrete package 200 improves its insulating characteristics and thermal transfer efficiency. To make the discrete package 200, however, a two-step soldering process is performed between the DBC substrate 210 and the leads, as well as between the DBC substrate 210 and the semiconductor chip 220. This two-step soldering process requires high manufacturing costs. Also, costs for manufacturing the DBC substrate 210 are more expensive (about eight times) than the costs for manufacturing a bare ceramic layer.

FIG. 3 is a cross-sectional view of still another conventional discrete package 300. As shown in FIG. 3, the discrete package 300 contains a lead frame pad 310 (which also acts as a heat sink) and a semiconductor chip 320 attached on an upper surface 310a of the lead frame pad 310 by a soldering process. The lead frame pad 310 and the semiconductor chip 320 are entirely encapsulated by a molding material 330. Since the lower surface 310b of the lead frame pad 310 is encapsulated by the molding material 330, the discrete package 300 can be insulated from the outside.

Manufacturing the discrete package 300 only requires a one-step soldering process between the lead frame pad 310 and the semiconductor chip 320, thereby reducing manufacturing costs. As well, using the molding material 330 enables the discrete package 300 to be insulated from the outside. Despite these advantages, however, the discrete package 300 is inconvenient to use because the thermal transfer efficiency of EMC (the material often used in the molding material 330) is more than ten times lower than those of ceramic materials.

### SUMMARY OF THE INVENTION

The present invention provides a discrete package having a high insulating and thermal transfer efficiency, yet which can be manufactured at a low cost.

According to one aspect of the present invention there is provided a discrete package containing: a lead frame pad with a first surface and a second surface, wherein the second surface is opposite the first surface; leads connected to a side of the lead frame pad; a semiconductor chip attached to the first surface of the lead frame pad; a ceramic layer which is positioned to directly contact the second surface of the lead frame pad; and a molding material which entirely encapsulates the lead frame pad, the semiconductor chip, and a portion of the ceramic layer, except the leads and the second surface of the ceramic layer.

According to another aspect of the present invention there is provided a discrete package containing: a lead frame pad which has a first surface and a second surface, the second surface being opposite the first surface; leads which are connected to a side of the lead frame pad; a semiconductor chip which is attached to the first surface of the lead frame pad; a ceramic layer which is attached with the second surface of the lead frame pad via an epoxy; and a molding material which entirely encapsulates the lead frame pad, the semiconductor chip, and a portion of the ceramic layer, except the leads and the second surface of the ceramic layer.

In both aspects of the invention, the leads can be formed to have steps with respect to the lead frame pad. As well, the discrete package can further include wires which electrically connect the leads to the semiconductor chip. Also, the lead frame pad can be formed to a thickness of 0.5 mm. Further, the discrete package can further include an adhesive between the lead frame pad and the semiconductor chip.

### BRIEF DESCRIPTION OF THE DRAWINGS

The above and other aspects and advantages of the present invention will become more apparent by describing in detail the preferred aspects thereof with reference to the attached drawings in which:

FIG. 1 is a cross-sectional view of a conventional discrete package;

FIG. 2 is a cross-sectional view of another conventional discrete package;

FIG. 3 is a cross-sectional view of still another conventional discrete package;

FIG. 4 is a plan view of an upper surface of a discrete package according to the present invention;

FIG. 5 is a plan view of a lower surface of a discrete package according to one aspect of the present invention;

FIG. 6 is a cross-sectional view of a discrete package according to one aspect of the present invention, taken along the line A-A′ of FIGS. 4 and 5;

FIG. 7 is cross-sectional view of a discrete package according to another aspect of the present invention, taken along the line A-A′ of FIGS. 4 and 5;

FIGS. 8 through 10 are views explaining a method of fabricating a discrete package according to an aspect of the present invention; and

FIG. 11 is a cross-sectional view explaining a method of fabricating a discrete package according to another aspect of the present invention.

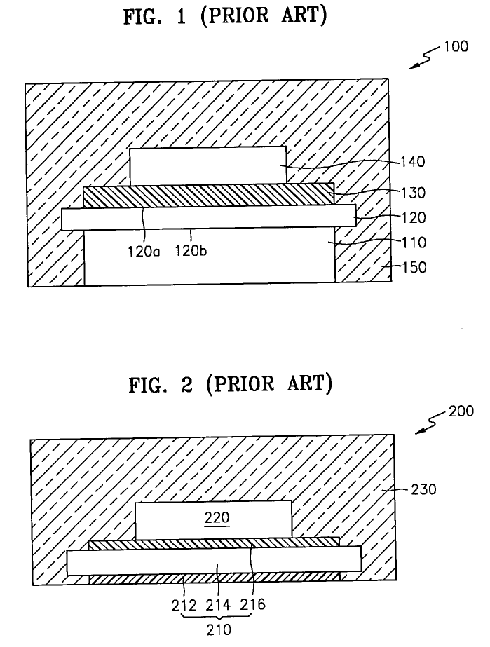

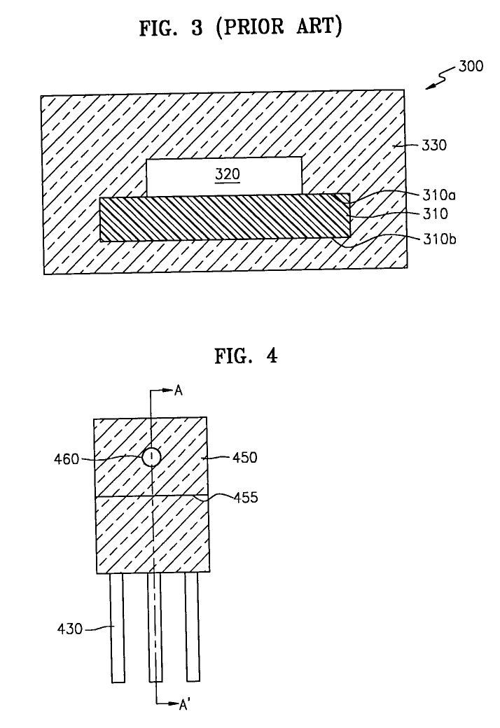

FIGS. 1-11 illustrate specific aspects of the invention and are a part of the specification. Together with the following description, the Figures demonstrate and explain the principles of the invention. In the drawings, the thickness of layers and regions are exaggerated for clarity. It will also be understood that when a layer is referred to as being “on” another layer or substrate, it can be directly on the other layer or substrate, or intervening layers may also be present. The same reference numerals in different drawings represent the same element, and thus their descriptions will not be repeated.

### DETAILED DESCRIPTION OF THE INVENTION

The present invention will now be described more fully with reference to the accompanying drawings, in which preferred aspects of the invention are shown. This invention may, however, be embodied in many different forms and should not be construed as being limited to the aspects set forth herein. Rather, these aspects are provided so that this disclosure will be thorough and complete and will fully convey the concept of the invention to those skilled in the art.

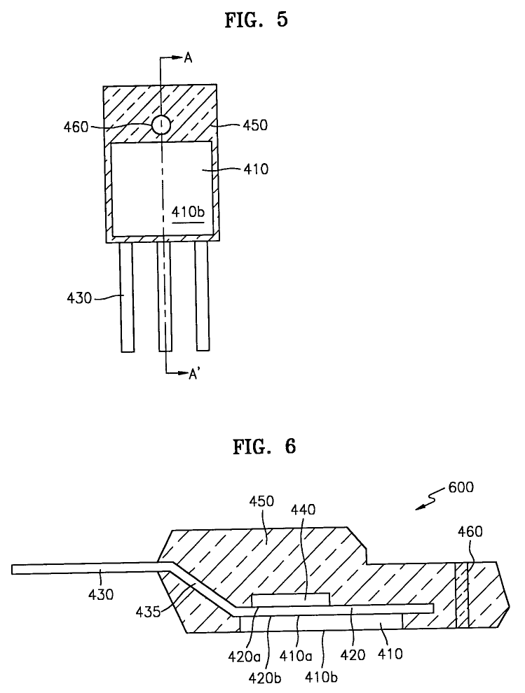

FIGS. 4 and 5 are plan views of upper and lower surfaces, respectively, of a discrete package according to one aspect of the present invention. As shown in FIG. 4, an upper surface of a molding material 450 in the discrete package is exposed. Leads 430 are formed on a side of the discrete package. There is no limit to the number of the leads 430 and the number may be determined according to the type of a semiconductor chip contained in the discrete package. In the aspect of the invention illustrated in FIGS. 4 and 5, the number of leads 430 is set to three for convenience. An upper surface of the discrete package contains a step 455. As depicted in FIG. 5, a portion of the molding material 450 and a lower surface 410b of a ceramic layer 410 are exposed at a lower surface of the discrete package.

FIG. 6 is a cross-sectional view of a discrete package 600 according to an aspect according to the present invention, taken along the line A-A′ of FIGS. 4 and 5. As illustrated in FIG. 6, the discrete package 600 contains a ceramic layer 410 (which operates as an insulating heat sink) having upper and lower surfaces 410a and 410b. The discrete package also contains a lead frame pad 420 formed on the ceramic layer 410 and a semiconductor chip 440 formed on the lead frame pad 420. The lead frame pad 420 has upper and lower surfaces 420a and 420b. Leads 430 are connected to a side of the lead frame pad 420 via a bent portion 435a. A portion of the ceramic layer 410, the lead frame pad 420, and the semiconductor chip 440 are entirely encapsulated by a molding material 450. Only the lower surface 410b of the ceramic layer 410 and a portion of the lead 430 are not encapsulated and therefore exposed to the outside the molding material 450. The discrete package also contains a groove 460 that is formed to pass through a portion of the molding material 450. When a screw is inserted into the groove 460, the discrete package 600 can be engaged with an outer heat sink (not shown).

An adhesive, such as a solder, may be positioned on the upper surface 420a of the lead frame pad 420 to adhere the semiconductor chip 440 to the lead frame pad 420. However, the lower surface 420b of the lead frame pad 420 is directly bonded to the upper surface 410a of the ceramic layer 410 without an adhesive. In other words, the lead frame pad 420 is bonded to the ceramic layer 410 by using the molding material 450. When manufacturing the discrete package 600, a soldering process is not performed between the ceramic layer 410 and the lead frame pad 420. Thus, there is no need to form a conductive layer pattern on the upper surface 410a of the ceramic layer 410 for the soldering process. Since the discrete package 600 uses the bare ceramic layer 410 (which can be fabricated at a cost of about three times less than a ceramic layer coated with a conductive layer pattern) as an insulating heat sink, the present invention is able to reduce the manufacturing costs. The ceramic layer 410 is also cheaper than using a DBC substrate, which is itself more expensive than the ceramic layer coated with the conductive layer pattern. Also, the thermal transfer efficiency of the discrete package 600 is higher than that of the discrete package 300 which is insulated using a portion of a molding material. In general, a semiconductor package containing EMC with a filler of 80 wt % (which is used as a molding material) has a thermal transfer efficiency of 2.09 W/m° C. at a temperature of about 25° C. A semiconductor package contains a ceramic layer (made of Al₂O₃ with 96 degree of purity) has a thermal transfer efficiency of 27 W/m° C. at a temperature of about 25° C.

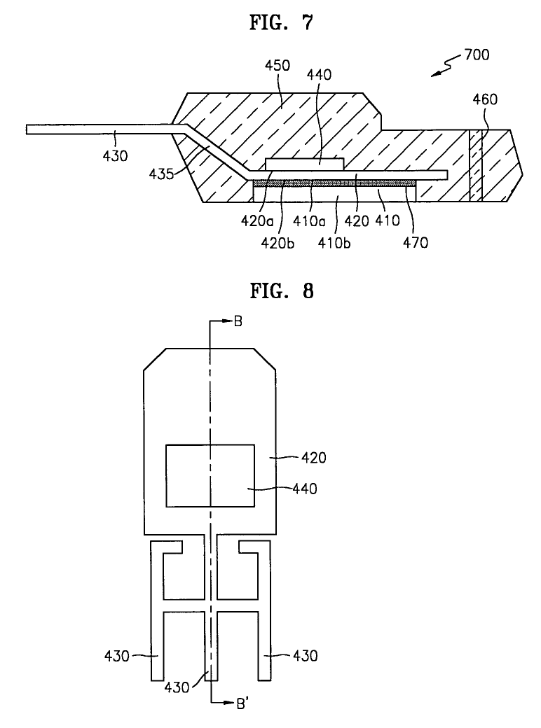

FIG. 7 is a cross-sectional view of a discrete package 700 according to another aspect of the present invention and is taken along the line A-A′ of FIGS. 4 and 5. In this aspect of the invention, elements that are the same as in FIG. 6 are indicated with the same reference numerals and their descriptions will not be repeated.

As shown in FIG. 7, the discrete package 700 is different from the discrete package 600 in that an epoxy 470 is used to bond the lower surface 420b of a lead frame pad 420 with the upper surface 410a of a ceramic layer 410 (which functions as an insulating heat sink). The epoxy 470 is formed to a thickness of about 20 μm and has a thermal transfer efficiency of 4 W/m° C. at a temperature of about 25° C. The discrete package 700 compensates for the disadvantages of the conventional discrete packages and yet has the same advantages as the discrete package 600.

Our experiments revealed that the conventional discrete package of FIG. 1 has a thermal resistance of 2.10° C./W while the discrete package 700 of FIG. 7 has a thermal resistance of 0.66° C./W. In other words, the thermal resistance of a discrete package according to the present invention is much lower than that of a comparable conventional package. In these experiments, the respective discrete packages shown in FIGS. 1 and 7 contained a lead frame pad having a thickness of 1.3 mm; an adhesive having a thickness of 20 μm, through which a semiconductor chip was bonded with the lead frame pad; a silicon semiconductor chip having a cross-sectional area of 5.8×4.9 mm² and a thickness of 0.3 mm; and an EMC encapsulant having a thickness of 0.4 mm. The discrete package of FIG. 7 contained a ceramic layer having a cross-sectional area of 8.8×72 mm² and a thickness of 0.5 mm, and an epoxy having a thickness of 20 μm through which the lead frame pad was bonded with the ceramic layer.

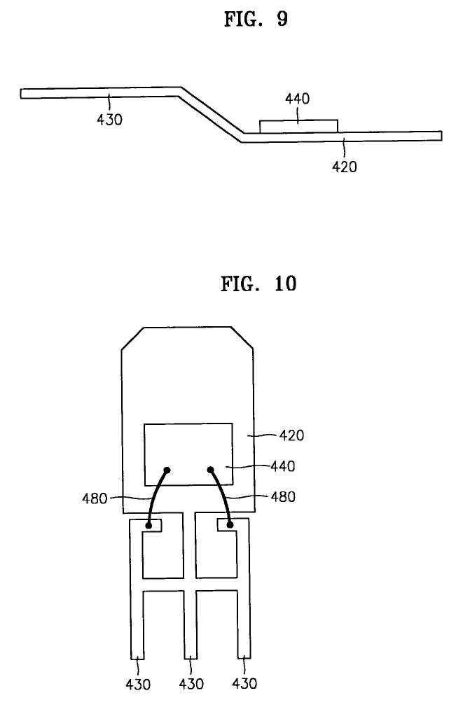

FIGS. 8 through 10 illustrate a method of fabricating a discrete package according to one aspect of the present invention. In particular, FIG. 9 is a cross-sectional view of a discrete package according to the present invention and is taken along the line B-B′ of FIG. 8.

As shown in FIGS. 8 and 9, a semiconductor chip 440 is attached to a chip bonding region of a lead frame pad 420. A side of the lead frame pad 420 is attached to leads 430. Although not shown in the drawings, the semiconductor chip 440 may be attached to the lead frame pad 420 using an adhesive, such as a solder. Next, as shown in FIG. 10, wire bonding is performed to electrically connect the semiconductor chip 440 to the leads 430 using wires 480. Thereafter, as shown in FIG. 6, the structure of FIG. 10 and a ceramic layer 410 are placed in molding equipment and a molding process as known in the art is performed using EMC as the molding material. Then, a general trimming process as known in the art is performed on the resulting structure to obtain a discrete package according to one aspect of the present invention.

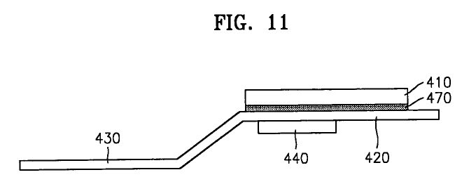

FIG. 11 is a cross-sectional view illustrating a method of fabricating a discrete package according to another aspect of the present invention. First, a method similar to that explained above (with reference to FIGS. 8 through 10) is carried out. Next, as shown in FIG. 11, a bare ceramic layer 410 is attached to a surface of a lead frame pad 420 using epoxy 470. The other surface of the lead frame pad 420 is then attached to a semiconductor chip 440. Thereafter, as shown in FIG. 7, general molding and trimming processes are performed on the resulting structure as known in the art to obtain a discrete package.

While this invention has been particularly shown and described with reference to preferred embodiments thereof, it will be understood by those skilled in the art that various changes in form and details may be made therein without departing from the spirit and scope of the invention as defined by the appended claims.

As described above, a discrete package according to the present invention uses a ceramic layer as an insulating heat sink, thereby increasing the thermal transfer efficiency of the discrete package. When manufacturing the discrete package, a soldering process is not performed to bond a lead frame pad with the ceramic layer. Therefore, the ceramic layer does not need to be coated with a conductive layer pattern. Consequently, the discrete package according to the present invention contains a bare ceramic layer that is cheaper than a ceramic layer coated with a conductive layer pattern, thereby reducing manufacturing costs.

What is claimed is:

1. A discrete package comprising:
a lead frame pad which has a first surface and a second surface, the second surface which is the opposite surface of the first surface;
leads connected to a side of the lead frame pad;
a semiconductor chip attached to the first surface of the lead frame pad;
a ceramic layer which is positioned to directly contact the second surface of the lead frame pad; and
a molding material which entirely encapsulates the lead frame pad, the semiconductor chip, and a portion of the ceramic layer, except the leads and the second surface of the ceramic layer.

2. The discrete package of claim 1, where the leads are formed to have steps with respect to the lead frame pad.

3. The discrete package of claim 1, further comprising wires which electrically connect the leads to the semiconductor chip.

4. The discrete package of claim 1, wherein the lead frame pad is formed to a thickness of 0.5 mm.

5. The discrete package of claim 1, further comprising an adhesive between the lead frame pad and the semiconductor chip.

6. A discrete package comprising:
a lead frame pad which has a first surface and a second surface, the second surface which is the opposite surface of the first surface;
leads which are connected to a side of the lead frame pad;
a semiconductor chip which is attached to the first surface of the lead frame pad;
a ceramic layer which is attached with the second surface of the lead frame pad via an epoxy; and
a molding material which entirely encapsulates the lead frame pad, the semiconductor chip, and a portion of the ceramic layer, except the leads and the second surface of the ceramic layer.

7. The discrete package of claim 6, wherein the leads are formed to have steps with respect to the lead frame pad.

8. The discrete package of claim 6, further comprising wires which electrically connect the leads to the semiconductor chip.

9. The discrete package of claim 6, wherein the lead frame pad is formed to a thickness of 0.5 mm.

10. The discrete package of claim 6, further comprising an adhesive between the lead frame pad and the semiconductor chip.

11. A discrete semiconductor package, comprising:
a lead frame having a first surface and a second surface with a lead connected to the lead frame;
a semiconductor chip attached to the first surface of the lead frame;
a ceramic layer having a first surface and a second surface, wherein the first surface of the ceramic layer is directly attached to the second surface of the lead frame; and
a molding material which encapsulates the lead frame, the semiconductor chip, a portion of the lead, and a portion of the second surface of the ceramic layer.

12. The package of claim 11, wherein the first surface of the ceramic layer does not contain a conductive layer.

13. The package of claim 11, wherein the ceramic layer is attached to the lead frame by using the molding material.

14. A discrete semiconductor package, comprising:
a lead frame having a first surface and a second surface with a lead connected to the lead frame;
a semiconductor chip attached to the first surface of the lead frame;
a ceramic layer having a first surface and a second surface, wherein the first surface of the ceramic layer is attached to the second surface of the lead frame via an epoxy; and
a molding material which encapsulates the lead frame, the semiconductor chip, a portion of the lead, and a portion of the second surface of the ceramic layer.

15. An electronic apparatus containing a packaged semiconductor device, the device comprising:
a lead frame having a first surface and a second surface with a lead connected to the lead frame;
a semiconductor chip attached to the first surface of the lead frame;
a ceramic layer having a first surface and a second surface, wherein the first surface of the ceramic does not contain a conductive layer and is attached to the second surface of the lead frame; and
a molding material which encapsulates the lead frame, the semiconductor chip, a portion of the lead, and a portion of the second surface of the ceramic layer.

16. The apparatus of claim 15, wherein the first surface of the ceramic layer is directly attached to the second surface of the lead frame.

17. The apparatus of claim 15, wherein the ceramic layer is attached to the lead frame by using the molding material.

18. The apparatus of claim 15, wherein the ceramic layer is attached to the lead frame via an epoxy located between ceramic layer and the lead frame.

19. A method for making a packaged semiconductor device, comprising:
providing a lead frame having a first surface and a second surface with a lead connected to the lead frame;
providing a semiconductor chip attached to the first surface of the lead frame;
providing a ceramic layer having a first surface and a second surface, wherein the first surface of the ceramic does not contain a conductive layer and is attached to the second surface of the lead frame; and
providing a molding material which encapsulates the lead frame, the semiconductor chip, a portion of the lead, and a portion of the second surface of the ceramic layer.

20. A method for making a packaged semiconductor device, comprising:
providing a lead frame having a first surface and a second surface with a lead connected to the lead frame;
attaching a semiconductor chip to the first surface of the lead frame;
attaching a first surface of a ceramic layer to the second surface of the lead frame, wherein the first surface of the ceramic layer does not contain a conductive layer; and
encapsulating the lead frame, the semiconductor chip, a portion of the lead, and a portion of a second surface of the ceramic layer.

21. The method of claim 20, farther comprising directly attaching the first surface of the ceramic layer to the second surface of the lead frame.

22. The method of claim 20, wherein the encapsulation is performed using a molding material.

23. The method of claim 22, further comprising attaching the ceramic layer to the lead frame by using the molding material.

24. The method of claim 20, further comprising attaching the ceramic layer to the lead frame by using an epoxy.

25. A method for making an electronic apparatus, comprising:
providing a packaged semiconductor device by providing a lead frame having a first surface and a second surface with a lead connected to the lead frame, attaching a semiconductor chip to the first surface of the lead frame, attaching a first surface of a ceramic layer to the second surface of the lead frame, wherein the first surface of the ceramic layer does not contain a conductive layer, and encapsulating the lead frame, the semiconductor chip, a portion of the lead, and a portion of a second surface of the ceramic layer;
providing an outer heat sink; and
connecting the packaged semiconductor device to the outer heat sink.
